(19) United States
(12) Patent Application Publication
(10) Pub. No.: US 2025/0329374 A1
(43) Pub. Date: Oct. 23, 2025

(54) NEUROMORPHIC DEVICE

(71) Applicant: SAMSUNG ELECTRONICS CO., LTD., Suwon-si (KR)

(72) Inventor: Youngnam HWANG, Suwon-si (KR)

(73) Assignee: SAMSUNG ELECTRONICS CO., LTD., Suwon-si (KR)

(21) Appl. No.: 18/943,196

(22) Filed: Nov. 11, 2024

(30) Foreign Application Priority Data
Apr. 23, 2024 (KR) 10-2024-0053753

(51) Int. Cl. G11C 11/4091; G11C 11/4093; G11C 11/4096

(52) U.S. Cl. CPC G11C 11/4091; G11C 11/4093; G11C 11/4096

(57) ABSTRACT

A neuromorphic device includes a first memory cell array, a second memory cell array, and an analog-to-digital converter (ADC) circuit connected to the first memory cell array through a plurality of bit lines and connected to the second memory cell array through a plurality of reference bit lines. The ADC circuit includes a plurality of sense amplifiers configured to compare a plurality of read currents output through the plurality of bit lines with a plurality of reference currents output through the plurality of reference bit lines, and a plurality of encoders connected to the plurality of sense amplifiers, and configured to respectively collect the comparison result signals output from connected sense amplifiers, and output digital signals based on the collected comparison result signals.

### CROSS-REFERENCE TO RELATED APPLICATION(S)

This application is based on and claims benefit of priority to Korean Patent Application No. 10-2024-0053753 filed on Apr. 23, 2024, in the Korean Intellectual Property Office, the disclosure of which is incorporated herein by reference in its entirety.

### BACKGROUND

### 1. Field

The disclosure relates to a neuromorphic device.

### 2. Description of Related Art

A neuromorphic device is a semiconductor device configured to replicate an information processing method of a brain by manufacturing an artificial nervous system on a neuron level. The neuromorphic device may implement deep learning neural networks, neuromorphic computing, and the like. The neuromorphic device may perform multiply and accumulate (MAC) operations, such as multiplying input data by weights and summing the multiplication results. The neuromorphic device may include a plurality of memory cells for storing weights in a data form for performing operations.

### SUMMARY

According to an aspect of the disclosure, there is provided a neuromorphic device that can improve the performance of multiply and accumulate (MAC) operations by shortening the time to convert read currents output from bit lines into digital values.

According to an aspect of the disclosure, there is provided a neuromorphic device including: a first memory cell array including a plurality of first memory cells configured to store weights of a neural network, a second memory cell array including a plurality of second memory cells, a word line driver connected to the plurality of first memory cells through a plurality of first word lines and connected to the plurality of second memory cells through a plurality of second word lines, and an analog-to-digital converter (ADC) circuit connected to the plurality of first memory cells through a plurality of first bit lines and connected to the plurality of second memory cells through a plurality of second bit lines, wherein the ADC circuit includes: a plurality of sense amplifiers, and a plurality of encoders, wherein each of the plurality of sense amplifiers is configured to compare a respective read current among a plurality of read currents output through the plurality of first bit lines with each of a plurality of reference currents output through the plurality of second bit lines, and respectively output comparison result signals, and wherein each of the plurality of encoders is connected to a respective sense amplifier among the plurality of sense amplifiers, and each of the plurality of encoders configured to: collect the comparison result signals output from the respectively connected sense amplifiers until the read current from the respectively connected sense amplifier is compared with all of the plurality of reference currents, and output digital signals based on the collected comparison result signals.

According to an aspect of the disclosure, there is provided a neuromorphic device including: a memory cell array including a plurality of memory cells configured to store weights of a neural network, a word line driver connected to the plurality of memory cells through a plurality of word lines, and an analog-to-digital converter (ADC) circuit connected to the plurality of memory cells through a plurality of bit lines, the ADC circuit configured to: repeat a comparison operation and a collection operation, the comparison operation including simultaneously comparing each of a plurality of read currents output through the plurality of bit lines with different reference currents among a plurality of reference currents, and the collection operation including collecting comparison result signals of each of the read currents until each of the read currents is compared with all of the plurality of reference currents, and convert the read currents into digital signals based on the comparison result signals collected for each of the read currents.

According to an aspect of the disclosure, there is provided a neuromorphic device including: a memory cell array including a plurality of memory cells configured to store weights of a neural network, a word line driver connected to the plurality of memory cells through a plurality of word lines, and an analog-to-digital converter (ADC) circuit connected to the plurality of memory cells through a plurality of bit lines, the ADC including: a plurality of unit circuits, each of the plurality of unit circuits configured to: generate comparison result signals by comparing one read current among a plurality of read currents output through the plurality of bit lines with a plurality of reference currents sequentially, collect the comparison result signals until the one read current is compared with all of the plurality of reference currents, and output a first digital signal based on the collected comparison result signals, a control circuit configured to control the plurality of unit circuits to simultaneously perform a comparison operation using different reference currents.

According to an example embodiment of the disclosure, a neuromorphic device may simultaneously perform an operation of comparing read currents output from bit lines with a plurality of different reference currents using a plurality of comparison circuits, thereby shortening the time to convert the read currents into digital values. Accordingly, the performance of MAC operations may be improved.

The aspects to be solved by the disclosure are not limited to the above-mentioned aspects, and other aspects not mentioned herein will be clearly understood by those skilled in the art from the following description.

### BRIEF DESCRIPTION OF DRAWINGS

The above and other aspects, features, and advantages of the disclosure will be more clearly understood from the following detailed description, taken in conjunction with the accompanying drawings, in which:

FIGS. 1A and 1B are view illustrating a neural network implemented by a neuromorphic device according to an example embodiment of the disclosure;

FIGS. 2A and 2B are view illustrating a cell array included in a neuromorphic device according to an example embodiment of the disclosure;

FIG. 3 is a view illustrating a neuromorphic device according to an example embodiment of the disclosure;

FIG. 4 is a view illustrating an operation of a neuromorphic device according to an example embodiment of the disclosure;

FIG. 5 is a flowchart illustrating an operation of a neuromorphic device according to an example embodiment of the disclosure;

FIG. 6 is a view schematically illustrating an ADC circuit according to an example embodiment of the disclosure;

FIG. 7 is a flowchart illustrating an operation of a neuromorphic device according to an example embodiment of the disclosure;

FIG. 8 is a view illustrating an ADC circuit according to an example embodiment of the disclosure in detail;

FIG. 9 is a view illustrating a priority encoder according to an example embodiment of the disclosure in detail; and

FIGS. 10 and 11 are schematic views illustrating a semiconductor device including a neuromorphic device according to an example embodiment of the disclosure.

### DETAILED DESCRIPTION

Hereinafter, example embodiments of the disclosure will be described with reference to the accompanying drawings.

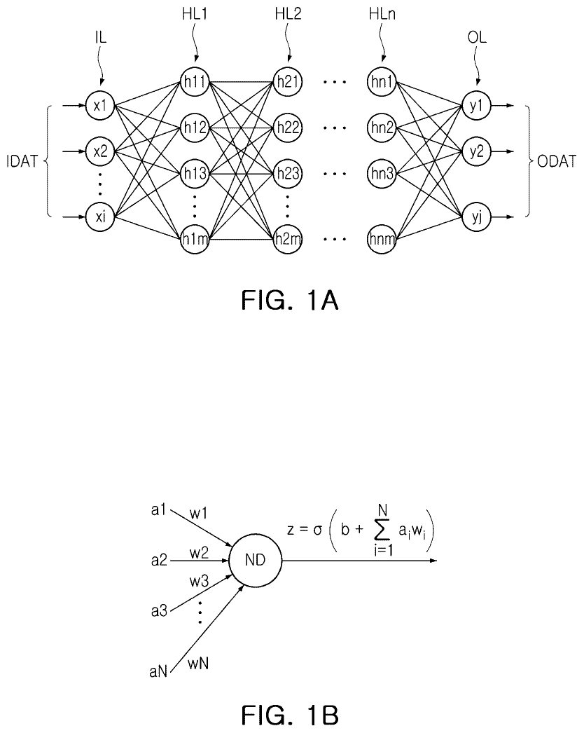

FIGS. 1A and 1B are view illustrating a neural network implemented by a neuromorphic device according to an example embodiment of the disclosure.

Referring to FIG. 1A, a network structure of a general neural network may include an input layer IL, a plurality of hidden layers HL1 to HLn, and an output layer OL. The input layer IL may include i (where i is a natural number) input nodes (x1 to xi), and vector input data IDAT having length i may be input to each input node.

Input data IDAT may be input to a hidden layer including n (where n is a natural number) hidden layers (HL1 to HLn), and each of the hidden layers HL1 to HLn may include hidden nodes. For example, a first hidden layer HL1 may include m (where m is a natural number) hidden nodes (h11 to hm), and an nth hidden layer HLn may include m hidden nodes hn1 to hnm.

In an example illustrated in FIG. 1A, each of the hidden layers HL1 to HLn includes the same number of hidden nodes. However, the disclosure is not limited thereto, and as such, according to another example, at least a portion of the hidden layers HL1 to HLn may include different numbers of hidden nodes. For example, one or more of the hidden layers HL1 to HLn may include a numbers of hidden nodes different than m. For example, a first hidden layer HL1 may include m layers and a second hidden layer HL2 may include p layers, where p is a natural number different than m.

The output layer OL may include j (where j is a natural number) output nodes (y1 to yj) corresponding to a class to be classified. For example, the output layer OL may output a result for each class as output data ODAT with respect to the input data IDAT. For example, the output layer OL may output a score or a class score for each class as the output data ODAT

The neural network illustrated in FIG. 1A may include a branch between two nodes illustrated as a straight line, and a weight used in each branch. In this case, nodes included in one layer may not be connected to each other, and nodes included in different layers may be completely or partially connected.

Each node in FIG. 1A may receive an output of a previous node and perform calculations, and output the calculation results to a next node. In this case, each node may calculate a value to be output by applying an input value to a specific function. For example, the specific function may be a non-linear function.

According to an embodiment, a neural network structure may be predetermined, and weights according to the branch between nodes may be determined as appropriate values using a data set for which a correct answer is already known. The data set used to determine the weights for which the correct answer is already known may be referred to as learning data, and a process of determining weights using learning data may be referred to as learning.

FIG. 1B illustrates an example embodiment of an arithmetic operation performed at one node ND among the nodes included in the neural network of FIG. 1A. Referring to FIG. 1B, in an example case in which N inputs (a1 to aN) are provided to one node ND, the node ND may multiply the N inputs (a1 to aN) and N weights (w1 to wN) corresponding thereto, add the multiplied results, and add an offset b to the added value. Additionally, the node ND may generate one output value z by applying a value in which the offset is reflected to a specific function σ.

In an example case in which one of the layers included in the neural network according an example embodiment illustrated in FIG. 1A includes M nodes (e.g., ND as illustrated in FIG. 1B), output values of the one layer may be obtained as illustrated in Equation 1 below.

$$Z = W * A \qquad ( 1 )$$

In Equation (1), W represents weights corresponding to all branches included in the one layer, and may be expressed in the form of an M×N matrix. A represents N inputs (a1 to aN) received by the one layer, and may be expressed in the form of an N×1 matrix. Z represents M outputs (z1 to zM) output from the one layer, and may be expressed in the form of an M×1 matrix.

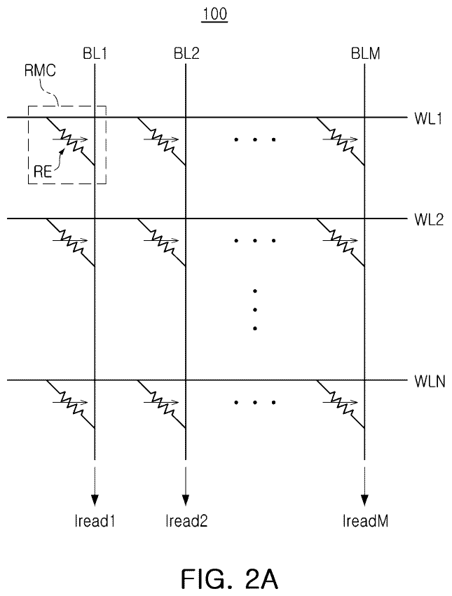

FIGS. 2A and 2B are view illustrating a cell array included in a neuromorphic device according to an example embodiment of the disclosure.

Referring to FIG. 2A, a first memory cell array 100 may include a plurality of resistive memory cells RMC provided in a region in which a plurality of word lines (WL1, WL2, . . . , WLN: WL1 to WLN) and a plurality of bit lines (BL1, BL2, . . . , BLM: BL1 to BLM) intersect each other. Each of the plurality of resistive memory cells RMC may include a resistive element RE, and may be connected to one of the plurality of word lines WL1 to WLN and one of the plurality of bit lines BL1 to BLM. For example, a first resistive element RE may be electrically connected between a first word line WL1 and a first bit line BL1.

A resistance value of the resistive element RE may change depending on a write voltage applied through the plurality of word lines WL1 to WLN and/or the plurality of bit lines BL1 to BLM, and the plurality of resistive memory cells RMC may store data by changing the resistance.

In an example case in which the write voltage is applied to a selected word line and a ground voltage (e.g., about 0V) is applied to a selected bit line, data ‘1’ may be written to a selected resistive memory cell, and in an example case in which the ground voltage is applied to the selected word line and the write voltage is applied to the selected bit line, data ‘O’ may be written to the selected resistive memory cell. According to an embodiment, in an example case in which a read voltage is applied to the selected word line and the ground voltage is applied to the selected bit line, data written to the selected resistive memory cell may be read.

In an example embodiment, each of the plurality of resistive memory cells RMC may be implemented by including any type of resistive memory cell. For example, the resistive memory cells RMC may include, but is not limited to, phase change random access memory (PRAM) cell, a resistance random access memory (RRAM) cell, a Magnetic Random Access Memory (MRAM) cell, a Ferroelectric Random Access Memory (FRAM) cell, or the like.

In an example embodiment, the resistive element RE may include a phase-change material in which a crystal state thereof changes depending on the amount of current. The phase change material may use various types of materials, such as GaSb, InSb, InSe, Sb2Te3 and GeTe, which are obtained by combining two elements, GeSbTe, GaSeTe, InSbTe, SnSb2Te4 and InSbGe, which are obtained by combining three elements, and AgInSbTe, (GeSn)SbTe, GeSb(SeTe) and Te81Ge15Sb2S2, which are obtained by combining four elements. In another example embodiment, the resistive element RE may also include perovskite compounds, transition metal oxide, magnetic materials, ferromagnetic materials, or antiferromagnetic materials. However, the resistive materials included in the resistive element RE is not limited to the above-mentioned materials.

FIG. 2B illustrates an example in which the first memory cell array 100 of FIG. 2A performs the arithmetic operation described with reference to FIGS. 1A and 1B.

Each of the resistive memory cells RMC may correspond to one synapse, or a branch in a neural network system, and may store a single weight. Mx N data stored in the first memory cell array 100 may be correspond to a weight matrix expressed in the form of the M×N matrix included in the one layer described with reference to FIGS. 2A and 2B, that is, W of Equation 1.

N input voltages (V1, V2, . . . , VN: V1 to VN) applied through the plurality of word lines WL1 to WLN may correspond to N inputs (a1, a2, . . . , aN: a1 to aN) received from the one layer, and may correspond to an input matrix expressed in the form of the N×1 matrix, that is, A of Equation 1.

M read currents (Iread1, Iread2, . . . , IreadM: Iread1 to IreadM) output through the plurality of bit lines BL1 to BLM may correspond to M outputs (z1, z2, . . . , zM: z1 to zM) output from the one layer, and may correspond to an output matrix expressed in the form of the M×1 matrix, that is, Z of Equation 1.

The first memory cell array 100 may be implemented by storing a plurality of weights in the form of a matrix in the plurality of resistive memory cells RMC. In an example case in which input voltages (V1, V2, . . . , VN: V1 to VN) corresponding to a plurality of input values are input to the first memory cell array 100 through a plurality of word lines WL1 to WLN, the read currents Iread1 to IreadM may be output through the plurality of bit lines BL1 to BLM. The read currents Iread1 to IreadM may be a result of a multiplication and accumulation (MAC) operation performed in a neural network system. In an example case in which all of the plurality of layers of the neural network system are implemented in this manner, a neuromorphic device for performing data storage and calculation operations at once may be implemented.

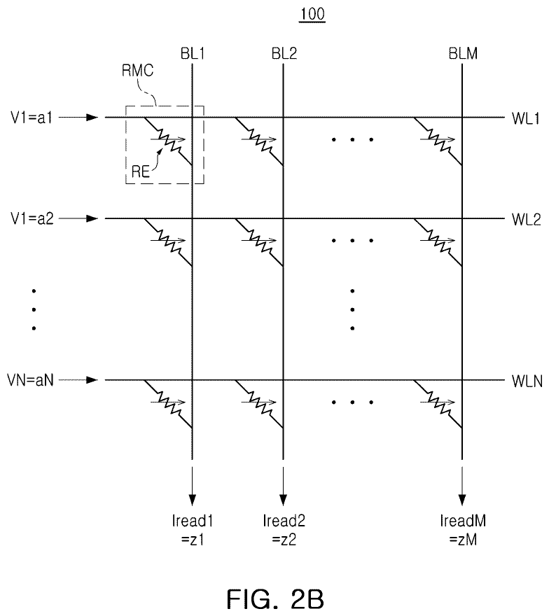

FIG. 3 is a view illustrating a neuromorphic device according to an example embodiment of the disclosure.

FIG. 3 illustrates a neuromorphic device 10 according to an example embodiment of the disclosure.

The neuromorphic device 10 may include a first memory cell array 100, a second memory cell array 200, a word line driver 150, an analog-to-digital converter (ADC) circuit 300 and an addition circuit 400.

As described with reference to FIGS. 1A and 1B, the neuromorphic device 10 may be used to drive any neural network system such as an artificial neural network (ANN) system, a convolutional neural network (CNN) system, a deep neural network (DNN) system and a deep learning system, and/or a machine learning system.

For example, the neuromorphic device 10 may be configured to execute and/or perform operations related to various services such as an image classification service, a user authentication service based on biometric information, an advanced Driver Assistance System (ADAS) service, a voice assistant service and an Automatic Speech Recognition (ASR) service, and/or applications.

As described with reference to FIGS. 2A and 2B, data stored in the first memory cell array 100 may be weights included in a plurality of layers constituting a neural network system, and a plurality of read currents Iread1 to IreadM may represent the result of an MAC operation performed by the neural network system. That is, the first memory cell array 100 may perform data storage and calculation operations at once.

The first memory cell array 100 may include a plurality of resistive memory cells RMC provided in a region in which a plurality of word lines WL1 to WLN (where N is a natural number of 2 or more) and a plurality of bit lines BL1 to BLM (where M is a natural number of 2 or more) intersect each other. Each of the plurality of resistive memory cells RMC may include a resistive element RE.

The first memory cell array 100 may store data. For example, data may be stored in the plurality of resistive memory cells RMC using a change in resistance of the resistive element RE included in each of the plurality of resistive memory cells RMC.

The plurality of word lines WL1 to WLN connected to the first memory cell array 100 may be driven by the word line driver 150. The first memory cell array 100 may output a plurality of read currents Iread1 to IreadM through an electrical path including the bit lines BL1 to BLM. The first memory cell array 100 may provide first to Mth read currents Iread1 to IreadM to the ADC circuit 300.

The second memory cell array 200 may include a plurality of reference resistive memory cells RRMC provided in a region in which a plurality of reference word lines (RWL1, RWL2, . . . , RWLN: RWL1 to RWLN) and a plurality of reference bit lines (RBL1, RBL2, . . . , RBLK: RBL1 to RBLK) (where N and K are natural numbers of 2 or more) intersect each other.

A plurality of reference word lines RWL1 to RWLN connected to the second memory cell array 200 may be driven by the word line driver 150. The second memory cell array 200 may output a plurality of reference currents Iref1 to IrefK through an electrical path including the reference bit lines RBL1 to RBLM. The second memory cell array 200 may provide first to Kth reference currents Iref1 to IrefK to the ADC circuit 300.

FIG. 3 illustrates an example embodiment in which the second memory cell array 200 is connected to a plurality of reference bit lines RBL1 to RBLK, but the disclosure is not limited thereto. For example, the second memory cell array 200 may be connected to one reference bit line. The number of reference bit lines connected to the second memory cell array 200 will be described below. Each of the plurality of reference resistive memory cells RRMC may include a resistive element RE. The second memory cell array 200 may have a similar structure to the first memory cell array 100 described with reference to FIGS. 2A and 2B.

In an example embodiment, each of the plurality of reference resistive memory cells RRMC included in the second memory cell array 200 may include the same resistive material as the plurality of reference resistive memory cells RMC included in the first memory cell array 100.

In an example embodiment, the number of reference bit lines connected to the second memory cell array 200 may be determined based on the precision of digital signals (DS1, DS2, . . . , DSM: DS1 to DSM) corresponding to the read currents Iread1 to IreadM, for example, the number of bits of the digital signals DS1 to DSM. In an example case in which each of the digital signals DS1 to DSM is an L bit signal (where L is a natural number), the number K of reference bit lines connected to the second memory cell array 200 may correspond to the number obtained by subtracting 1 from L square of 2. That is, this may be determined as K=2^{L}−1.

The word line driver 150 may drive a plurality of word lines WL1 to WLN connected to the first memory cell array 100, and drive a plurality of reference word lines RWL1 to RWLN connected to the second memory cell array 200.

For example, word line driver 150 may drive the plurality of word lines WL1 to WLN so that at least one selected word line among the plurality of word lines WL1 to WLN is activated based on element values of an input feature vector used in the calculation of the neuromorphic device 10. For example, the element values of the input feature vector may be determined based on N inputs (a1 to aN) described with reference to FIG. 1A.

In an example case in which each element value of an input feature vector of length N has ‘1’ or ‘0,’ the word line driver 150 may drive the plurality of word lines WL1 to WLN so that a word line corresponding to a position of an element having ‘1’ is activated.

The word line driver 150 may drive the plurality of reference word lines RWL1 to RWLN so that all of the plurality of reference word lines RWL1 to RWLN are activated, during an operation section of the neuromorphic device 10.

The ADC circuit 300 may convert the plurality of read currents Iread1 to IreadM into a plurality of digital signals DS1 to DSM using the plurality of reference currents Iref1 to IrefK, and may output the plurality of digital signals DS1 to DSM.

In an example embodiment, the plurality of reference currents Iref1 to IrefK may be output from the second memory cell array 200 including the same resistive material as the resistive element RE included in the first memory cell array 100. Since the plurality of resistive memory cells RMC may have temperature and time dependence, the plurality of read currents Iread1 to IreadM may also have temperature and time dependence. The plurality of reference currents Iref1 to IrefK may effectively reduce or eliminate the temperature and time dependence of the plurality of read currents Iread1 to IreadM. However, the disclosure is not limited to a case in which the plurality of reference currents Iref1 to IrefK are obtained from the second memory cell array 200.

The addition circuit 400 may performs accumulation and/or summation operations using the plurality of digital signals DS1 to DSM to generate output data ODAT. For example, the addition circuit 500 may output first output data ODAT1, and second output data ODAT2 to mth output data ODATM using the plurality of digital signals DS1 to DSM. In an example embodiment, the addition circuit 400 may include at least one adder and at least one shift register. The addition circuit 400 may be referred to as an adder or an adder circuit.

Meanwhile, the ADC circuit 300 may perform multiple comparison operations to convert the plurality of read currents Iread1 to IreadM into the plurality of digital signals DS1 to DSM. In an example case in which the comparison operations are to be performed sequentially, the time required for the comparison operations may be lengthened. The longer time required for the comparison operations may be a cause of deterioration in MAC operation performance of the neuromorphic device 10.

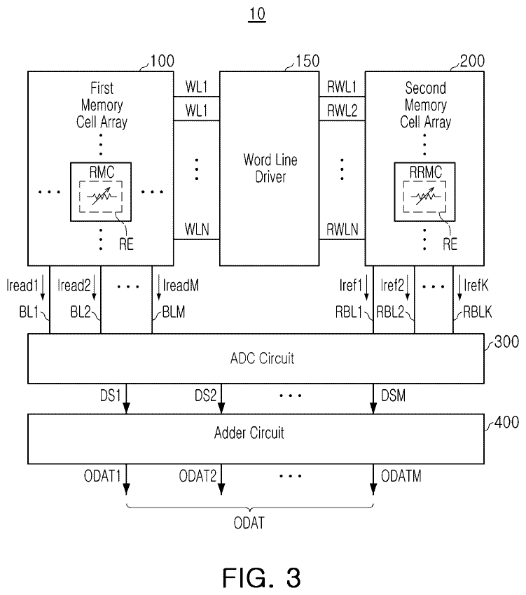

According to an example embodiment of the disclosure, the ADC circuit 300 may reduce the time required for comparison operations by parallelizing a plurality of comparison operations, and improve MAC calculation performance. Hereinafter, before describing the structure and operation of the ADC circuit 300 according to an example embodiment of the disclosure, an operation of converting the plurality of read currents Iread1 to IreadM into the plurality of digital signals DS1 to DSM will be described with reference to FIG. 4.

FIG. 4 is a view illustrating an operation of a neuromorphic device according to an example embodiment of the disclosure.

In the neuromorphic device 10 described with reference to FIG. 3, the ADC circuit 300 may obtain a read current Iread. The read current Iread may be a current obtained from one of the plurality of bit lines BL1 to BLM in a state in which the plurality of word lines WL1 to WLN are driven based on element values of an input feature vector. For example, the read current Iread may correspond to any of the read currents Iread1 to IreadM described with reference to FIG. 3.

The read current Iread may be converted into a digital signal in the ADC circuit 300. The ADC circuit 300 may compare the read current Iread with a plurality of reference currents. The number of reference currents compared to the read current Iread may be determined according to the precision of the ADC circuit 300. In an example case in which the ADC circuit 300 has a precision of 5 bits, 31 reference currents (Iref1 to Iref31) and the read current Iread may be compared.

A plurality of reference currents Iref1 to Iref31 may have an order of magnitude. According to an embodiment illustrated in FIG. 4, a magnitude of the first reference current Iref1 may be the smallest and the magnitude of the thirty-first reference current Iref31 may be the greatest. The magnitudes of the plurality of reference currents Iref1 to Iref31 may be determined based on data stored in a plurality of reference resistive memory cells RRMC of the second memory cell array 200. For example, as the number of memory cells in which data ‘1’ is recorded, among the reference resistive memory cells RRMC connected to a certain reference bit line, increases, the magnitude of the reference current output through the reference bit line may increase.

According to the embodiment illustrated in FIG. 4, the magnitude of the read current Iread may be greater than the magnitude of the third reference current Iref3 and may be smaller than the magnitude of a fourth reference current Iref4. In this case, the ADC circuit 300 may convert the read current Iread into a digital signal of [00011].

In order for the ADC circuit 300 to determine that the magnitude of the read current Iread is greater than the magnitude of the third reference current Iref3 and smaller than the magnitude of the fourth reference current Iref4, several comparison operations may be performed using the plurality of reference currents Iref1 to Iref31. In an example case in which the ADC circuit 300 performs comparison operations using reference currents selected from the plurality of reference currents Iref1 to Iref31 using a binary search technique, five comparison operations may be required.

In an example case in which different reference currents are used in multiple comparison operations for the read current Iread, it may be difficult to perform the multiple comparison operations simultaneously. This is because if the read current Iread output from one bit line is simultaneously connected to several paths, the magnitude of the current flowing through each path may be different from the read current Iread. Accordingly, the ADC circuit 300 may sequentially perform multiple comparison operations for one read current Iread.

In an example case in which multiple comparison operations should be performed sequentially for each of the read currents Iread1 to IreadM so as to convert the read currents the Iread1 to IreadM output from the plurality of bit lines BL1 to BLM into the digital signals DS1 to DSM, the time required for comparison operations may be lengthened.

According to an example embodiment of the disclosure, the ADC circuit 300 may shorten the time required for the comparison operations by parallelizing the comparison operations using different reference currents for the plurality of read currents.

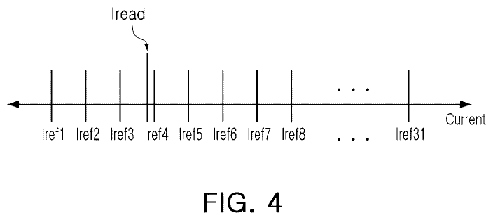

FIG. 5 is a flowchart illustrating an operation of a neuromorphic device according to an example embodiment of the disclosure.

Referring to FIG. 5, an operation in which a neuromorphic device converts read currents Iread1 to IreadM into digital signals DS1 to DSM may include operations S11 to S14. However, the disclosure is not limited thereto, and as such, one or more operations may be added, omitted or combined. The neuromorphic device may correspond to the neuromorphic device 10 described with reference to FIG. 3.

In operation S11, the method may include comparing each of a plurality of read currents output from a plurality of bit lines with a plurality of different reference currents. For example, the ADC circuit 300 may simultaneously compare each of the read currents output from a plurality of bit lines with different reference currents, and may output comparison result signals for each of the read currents.

In an example case in which a number of read currents and a number of reference currents of the neuromorphic device 10 are equal to 31, thirty-one comparison operations in which each of the first to thirty-first read currents Iread1 to Iread31 is compared with different reference currents of the first to thirty-first reference currents Iref1 to Iref31 may be performed simultaneously.

The ADC circuit 300 may pair each of the first to thirty-first read currents Iread1 to Iread31 with the first to thirty-first reference currents Iref1 to Iref31 in a specific order, and may simultaneously perform comparison operations for a plurality of read current and reference current pairs. The specific order may be a predetermined order. For example, the ADC circuit 300 may perform thirty-one comparison operations, such as simultaneously comparing the first read current Iread1 with the first reference current Iref1, comparing the second read current Iread2 with the second reference current Iref2, and comparing the third read current Iread3 with the third reference current Iref3, and the like.

In an example embodiment, the order of the first to thirty-first read currents Iread1 to Iread31 may be determined depending on identifiers of bit lines associated with the first to thirty-first read currents Iread1 to Iread31. Furthermore, the order of the first to thirteenth reference currents Iref1 to Iref31 may be determined according to the magnitudes of the first to thirteenth reference currents Iref1 to Iref31.

In operation S12, the method may include collecting comparison result signals of each read current. For example, the ADC circuit 300 may collect comparison result signals of each read current. As described with reference to FIG. 4, each of the read currents may be converted into digital signals using comparison results based on a plurality of reference currents. Accordingly, the ADC circuit 300 may collect the comparison result signals to convert each of the read currents into digital signals.

For example, the ADC circuit 300 may collect 31 comparison result signals, including a first comparison result signal obtained by comparing the first read current Iread1 with the first reference current Iref1, and a second comparison result signal obtained by comparing the second read current Iread2 with the second reference current Iref2.

Taking the first read current Iread1 as an example, a digital signal corresponding to the first read current Iread1 may not be determined using only the first comparison result signal indicating a result of comparison with the first reference current Iref1. However, in an example case in which all the comparison results from the second reference current Iref2 to the thirty-first reference current Iref31 are collected while repeating the specified operations, the ADC 300 may determine a digital signal corresponding to the first read current Iread1.

In operation S13, the method may include determining whether each of the read currents has been compared to all of the different reference currents. For example, the ADC 300 may determine whether each of the read currents has been compared to all reference currents. For example, the ADC 300 may count whether the specified operations have been performed repeatedly 31 times, thus determining whether each of the first to thirty-first read currents Iread1 to Iread31 is compared with all of the first to thirty-first reference currents Iref1 to Iref31.

In an example case in which each of the read currents is not compared to all reference currents (in operation S13, “No”), the ADC 300 may change the reference currents paired with each of the first to thirty-first read currents Iread1 to Iread31 and may perform iteration including operations S11 to S13. For example, the ADC 300 may pair each of the first to thirty-first read currents Iread1 to Iread31 with another one of the reference currents to which the respect read current was not previously paired.

For example, the ADC circuit 300 may change the paired reference current to a next reference current in the order, in the plurality of read current and reference current pairs, depending on a predetermined order of the first to thirty-first reference currents Iref1 to Iref31.

In an example case in which the ADC circuit 300 compares the first read current Iread1 with the first reference current Iref1 in a previous iteration, the first read current Iread1 may be compared with the second reference current Iref2 in a current iteration. In an example case in which the second read current Iread2 is compared to the second reference current Iref2 in the previous iteration, the second read current Iread2 may be compared with the third reference current Iref3 in the current iteration, and in an example case in which the thirty-first read current Iread31 is compared with the thirty-first reference current Iref31 in the previous iteration, the thirty-first read current Iread31 may be compared with the first reference current Iref1 in the current iteration.

In an example case in which each of the read currents is compared to all reference currents (in operation S13, “Yes”), the ADC 300 may convert output signals corresponding to the bit lines into digital signals based on the comparison result signals collected in operation S14.

In an example case in which the iteration including operations S11 to S13 is performed 31 times, for each of the first to thirty-first read currents Iread1 to Iread31, comparison result signals with the first to thirty-first reference currents Iref1 to Iref31 may be collected. The ADC 300 may convert each of the first to thirty-first read currents Iread1 to Iread31 into digital signals DS1 to DS31 using the comparison result signals.

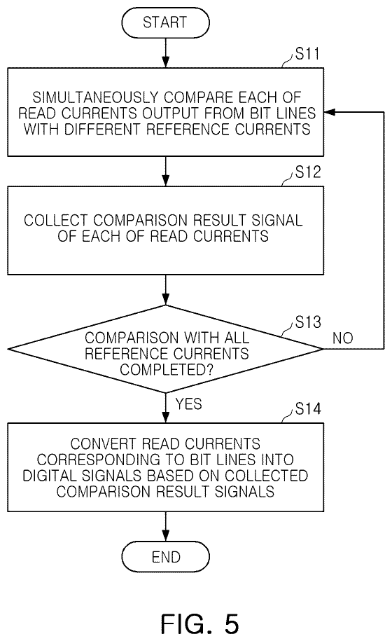

Hereinafter, a structure of an ADC circuit for converting read currents Iread1 to IreadM into the digital signals DS1 to DSM will be described with reference to FIG. 6.

FIG. 6 is a view schematically illustrating an ADC circuit according to an example embodiment of the disclosure.

Referring to FIG. 6, an ADC circuit 300 may include a plurality of multiplexers (311, 312, . . . , 31K: 311 to 31K), a plurality of sense amplifiers 321, 322, . . . , 32K: 321 to 32K), a plurality of demultiplexers (331, 332, . . . , 33K: 331 to 33K), a plurality of encoders (341, 342, . . . , 34K: 341 to 34K), and a control circuit 350. The ADC circuit 300 of FIG. 6 may correspond to the ADC circuit 300 described with reference to FIG. 3.

The ADC circuit 300 may include a plurality of multiplexers 311 to 31K, a plurality of sense amplifiers 321 to 32K, a plurality of demultiplexers 331 to 33K and a plurality of encoders 341 to 34K including the same number. In order to convert one read current into a digital signal, one multiplexer, one sense amplifier, one demultiplexer and one encoder may be connected to each other. The multiplexer, the sense amplifier, the demultiplexer and the encoder connected to each other to convert one read current into a digital signal may be referred to as a unit circuit. The ADC circuit 300 may include a plurality of unit circuits, and the plurality of unit circuits may have a parallel structure. For example, each of the plurality of unit circuits are configured to operate in a parallel manner.

Each of the plurality of sense amplifiers 321 to 32K may compare different read currents with different reference currents, and may output comparison result signals. The plurality of sense amplifiers 321 to 32K may have a parallel structure in the ADC circuit 300 and may perform a comparison operation simultaneously.

The number of sense amplifiers 321 to 32K may be equal to the number of reference currents. In an example case in which the number of reference currents (Iref[1:31]: Iref1 to Iref31) is 31, the number of sense amplifiers 321 to 32K may also be 31.

The plurality of sense amplifiers 321 to 32K may include a first input unit through which a read current is input, a second input unit through which a reference current is input, and an output unit through which a comparison result signal is output. In an example embodiment, the comparison result signal may be a voltage signal.

According to an embodiment illustrated in FIG. 6, the number of read currents Iread1 to Iread31 may be equal to the number of reference currents Iref1 to Iref31. A different one of the read currents Iread1 to Iread31 may be input to the first input unit of each of the sense amplifiers 321 to 32K. A different one of the reference currents Iref1 to Iref31 may be input to the second input unit of each of the sense amplifiers 321 to 32K.

In an example embodiment, one read current may be fixedly input to the first input unit of each of the sense amplifiers 321 to 32K, and the first to thirty-first reference currents Iref1 to Iref31 may be input to the second input unit in a predetermined order until comparison operations for all reference currents Iref1 to Iref31 are completed.

Reference currents input to the plurality of sense amplifiers 321 to 32K may be output from the plurality of multiplexers 311 to 31K. The plurality of multiplexers 311 to 31K may receive the plurality of reference currents Iref1 to Iref31 from connected reference bit lines, and may output a reference current selected depending on a control signal from the control circuit 350.

In an example embodiment, the control circuit 350 may control the reference currents Iref1 to Iref31 to be input to the plurality of sense amplifiers 321 to 32K in a predetermined order. Additionally, the control circuit 350 may change the reference current input to each of the plurality of sense amplifiers 321 to 32K to a reference current in a next order, depending on the order determined by the reference currents Iref1 to Iref31 whenever one comparison operation is performed.

FIG. 6 illustrates a case in which in the first sense amplifier 321, the reference currents are input in the order of the first reference current Iref1, the second reference current Iref2, the third reference current Iref3, . . . , the thirtieth reference current Iref30 and the thirty-first reference current Iref31. While the reference currents are input to the first sense amplifier 321 in the predetermined order, the reference currents may be input in the second sense amplifier 322 in the order of the second reference current Iref2, the third reference current Iref3, . . . , the thirty-first reference current Iref31 and the first reference current Iref1. Additionally, the reference currents may be applied to the thirty-first sense amplifier 32K in the order of the thirty-first reference current Iref31, the first reference current Iref1, the second reference current Iref2, . . . , the twenty-ninth reference current Iref29 and the thirtieth reference current Iref30.

However, the disclosure is not limited thereto, and the control circuit 350 may control the plurality of multiplexers 311 to 31K to output different reference currents in any different order.

Each of the plurality of encoders 341 to 34K may receive comparison result signals obtained by comparing the read current with the plurality of reference currents Iref1 to Iref31, and may convert the read current into a digital signal using the comparison result signals. Each of the plurality of encoders 341 to 34K may include a plurality of input terminals I1 to I31 corresponding to each of the comparison result signals, and a plurality of output terminals O0 to O4 corresponding to a plurality of bits included in the digital signal. Each of the plurality of encoders 341 to 34K may further include an input terminal I0 receiving a power signal VCC.

The plurality of encoders 341 to 34K may be priority encoders. In the priority encoder, input signals input to the input terminals I1 to I31 may have different priorities. In an example case in which the input signals are activated simultaneously, an input signal having the highest priority may be encoded. For example, the comparison result signals may be input to the input terminals I1 to I31 depending on the order of magnitude of the first to thirty-first reference currents Iref1 to Iref31 so that a signal obtained based on a reference current with a higher magnitude, among a plurality of comparison result signals, has a higher priority,

In an example case in which a magnitude of the read current is greater than a magnitude of the third reference current Iref3 and smaller than a magnitude of the fourth reference current Iref4, a value of ‘1,’ comparison result signals by the first to third reference currents Iref1 to Iref3, may be input to the first to third input terminals I1 to I3 among the input terminals I1 to I31, and a value of ‘0,’ comparison result signals by the fourth to thirty-first reference currents Iref4 to Iref31, may be input to the remaining input terminals I4 to I31. The encoder may output a digital signal of by encoding the ‘1’ value of the third input terminal I3.

Each of the plurality of demultiplexers 331 to 33K may provide a comparison result signal output from a sense amplifier connected to the demultiplexer to one of the plurality of input terminals I1 to I31 of the encoder connected to the demultiplexer. For example, the plurality of demultiplexers 331 to 33K may select one of the plurality of input terminals I1 to I31 based on the magnitude of the reference current used for the comparison operation in the sense amplifier, and may output the comparison result signal to the selected input terminal.

Each of the plurality of encoders 341 to 34K may collect comparison result signals using each of the first to thirty-first reference currents Iref1 to Iref31 through the plurality of input terminals I1 to I31. In an example embodiment, each of the plurality of encoders 341 to 34K may include buffers for temporarily storing comparison result signals.

Once the collection of comparison result signals is completed, each of the plurality of encoders 341 to 34K may output the digital signal through the output terminals O0 to O4 by performing priority encoding.

According to an example embodiment of the disclosure, the ADC circuit 300 may simultaneously process a plurality of comparison operations for a plurality of read currents Iread1 to Iread31 by inputting different read currents and different reference currents to each of the plurality of sense amplifiers 321 to 32K connected in parallel. Accordingly, the time required for the ADC circuit 300 to convert a plurality of read currents Iread1 to Iread31 into digital signals may be reduced, and the MAC operation performance of the neuromorphic device 10 may be improved.

In an example case in which a comparison operation is performed by fixedly inputting different reference currents Iref1 to Iref31 to each of the plurality of sense amplifiers and selecting a sense amplifier to which a read current is applied depending on a reference current to be compared with the read current, at least five sequential comparison operations may be required to convert one read current into a digital signal. Accordingly, in order to convert the plurality of read currents Iread1 to Iread31 into digital signals, at least 5*31=155 sequential comparison operations may be required.

On the other hand, according to an example embodiment of the disclosure, comparison result signals using a plurality of reference currents Iref1 to Iref31 for each of the plurality of read currents Iread1 to Iread31 may be obtained by repeating comparison operations performed simultaneously for different read currents Iread1 to Iread31 31 times. Accordingly, the time required to convert the plurality of read currents Iread1 to Iread31 into digital signals may be shortened by about ⅕.

Meanwhile, referring to FIGS. 5 and 6, an example embodiment of the disclosure has been described by taking the case in which the number of read currents and the reference currents are the same as an example. However, the disclosure is not limited thereto. For example, the number of read currents may be more or less than the number of reference currents. In the ADC circuit 300, the number of unit circuits including the multiplexer, the sense amplifier, the demultiplexer and the encoder may be equal to the number of reference currents. In an example case in which the number of read currents is greater than the number of reference currents, all read currents may not be input to the sense amplifiers 321 to 32K at the same time.

According to an example embodiment of the disclosure, in an example case in which the number of read currents is greater than the number of reference currents, target read currents to be input to the sense amplifiers 321 to 32K may be selected based on the number of unit circuits.

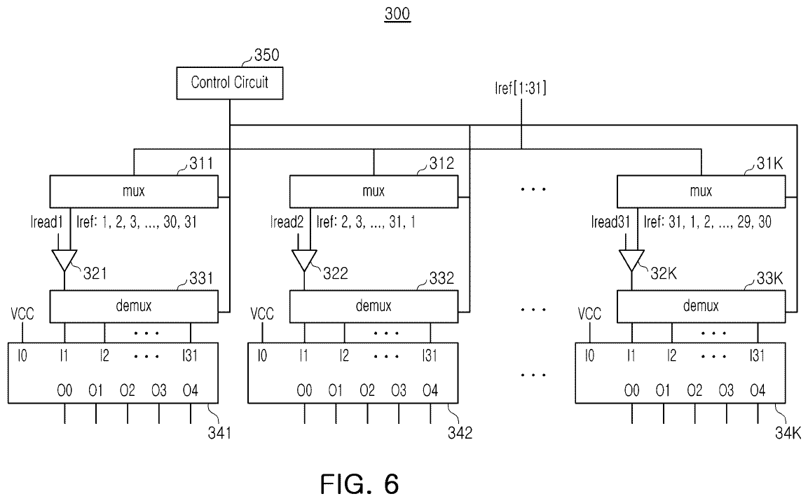

FIG. 7 is a flowchart illustrating an operation of a neuromorphic device according to an example embodiment of the disclosure.

Referring to FIG. 7, the operation in which the neuromorphic device converts the read currents Iread1 to IreadM into digital signals DS1 to DSM may include operations S21 to S26. The neuromorphic device may correspond to the neuromorphic device 10 described with reference to FIG. 3.

In operation S21, the method may include may selecting target bit lines from unselected bit lines. For example, the ADC circuit 300 may select target bit lines from unselected bit lines. For example, the target bit lines may be selected by the control circuit 350.

In an example case in which the number of unselected bit lines is larger than the number of reference bit lines, the same number of bit lines as the number of reference bit lines may be selected. In an example embodiment, the bit lines may be selected in order of a specified identifier. In an example case in which the neuromorphic device 10 has 90 bit lines from first to ninetieth bit lines BL1 to BL90 and has 31 bit lines of first to thirty-first reference bit lines RBL1 to RBL31, the ADC circuit first may select the first to thirty-first bit lines BL1 to BL31, may select thirty-second to sixty-second bit lines BL32 to BL62 in the following order, and may select sixty-third to ninetieth bit lines BL63 to BL90 in last order.

In operations S22 to S25, the method may include converting read signals output through the target bit lines selected in operation S21 into digital signals. For example, the ADC circuit 300 may convert read signals output through the target bit lines selected in operation S21 into digital signals. Operations S22 to S25 may be substantially the same as operations S11 to S14 described with reference to FIG. 5.

For example, different read signals and different reference signals output from the target bit lines may be input to each of a plurality of sense amplifiers 321 to 32K of the ADC circuit 300, and may simultaneously perform comparison operations in the plurality of sense amplifiers 321 to 32K. Comparison result signals output from the plurality of sense amplifiers 321 to 32K may be collected from each of a plurality of encoders 341 to 34K.

In an example case in which comparison operations for all reference currents in each of the plurality of sense amplifiers 321 to 32K are completed, comparison result signals corresponding to all reference currents for different read currents may be collected from each of the plurality of encoders 341 to 34K. Each of the plurality of encoders 341 to 34K may output digital signals corresponding to different read currents using the collected comparison result signals.

In operation S26, the method may include determining whether read currents for all bit lines have been converted to digital signals. For example, the ADC circuit 300 may determine whether read currents for all bit lines have been converted to digital signals.

In an example case in which the read currents for all bit lines are not converted (operation S26, “No”), the ADC circuit 300 may repeatedly perform operations S21 to S25. Additionally, in an example case in which the read currents for all bit lines are converted (“Yes” in operation S26), the ADC circuit 300 may terminate the operation.

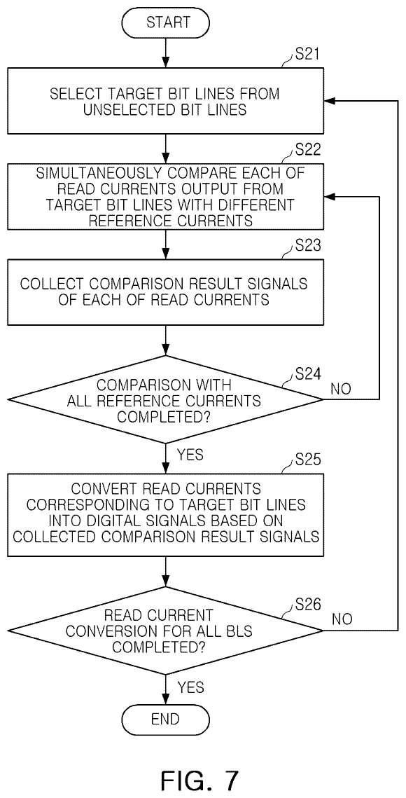

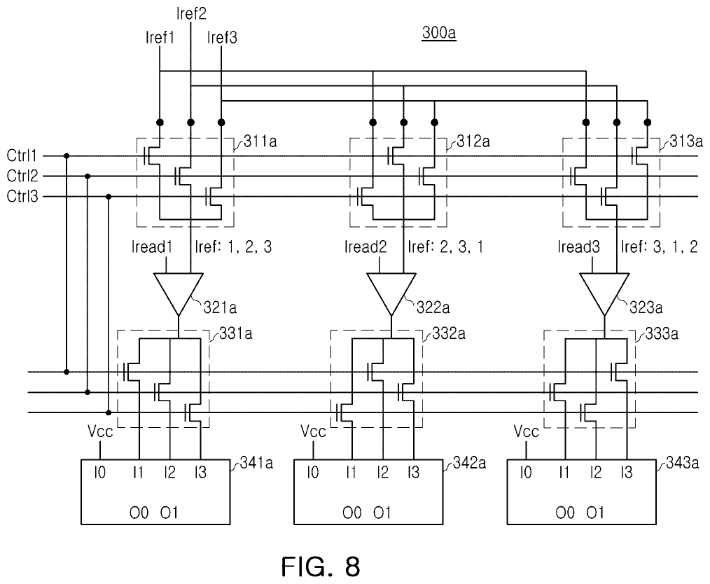

Hereinafter, with reference to FIGS. 8 and 9, an example embodiment of the structure of the ADC circuit according to an example embodiment of the disclosure will be described in detail.

FIG. 8 is a view illustrating an ADC circuit according to an example embodiment of the disclosure in detail.

Referring to FIG. 8, an ADC circuit 300a according to an embodiment is illustrated. For example, the ADC circuit 300a may have a similar structure to the ADC circuit 300 described with reference to FIG. 6. However, while the ADC circuit 300 of FIG. 6 is a circuit that converts each of 31 read currents into 5-bit digital signals using 31 reference currents, the ADC circuit 300a of FIG. 8 may be a circuit that converts three read currents Iread1 to Iread3 into 2-bit (O0, O1) digital signals by comparing the three read currents Iread1 to Iread3 using three reference currents Iref1, Iref2 and Iref3.

The ADC circuit 300a may include a plurality of multiplexers (311a, 312a, 313a: 311a to 313a), a plurality of sense amplifiers (321a, 322a, 323a: 321a to 323a), a plurality of demultiplexers (331a, 332a, 333a: 331a to 333a), and a plurality of encoders (341a, 342a, 343a: 341a to 343a).

The plurality of sense amplifiers 321a to 323a may simultaneously compare different read currents Iread1 to Iread3 with different reference currents Iref1 to Iref3, and may output comparison result signals.

The plurality of encoders 341a to 343a may collect the comparison result signals compared with a plurality of reference currents Iref1 to Iref3, for different read currents Iread1 to Iread3, and may generate and output digital signals using the comparison result signals.

Each of the multiplexers 311a to 313a may include a plurality of switch circuits controlled by a plurality of control signals Ctrl1 to Ctrl3. In an example case in which each of the plurality of switch circuits is turned on, a reference current may be provided as an input to the sense amplifier. According to an embodiment, the switch circuits may be implemented with transistors. However, the disclosure is not limited thereto and as such, the switch circuits may be implemented in another manner. According to an embodiment, the plurality of control signals Ctrl1 to Ctrl3 may be input by the control circuit as described in the example of FIG. 6.

The plurality of control signals Ctrl1 to Ctrl3 may be enabled in a selective manner, and based on the enabled control signal, one of the plurality of switch circuits in each of the plurality of multiplexers 311a to 313a may be turned on. For example, none of the plurality of control signals Ctrl1 to Ctrl3 may be enabled at the same time.

According to an example embodiment of the disclosure, the plurality of control signals Ctrl1 to Ctrl3 may control different reference currents to be input to each of the plurality of sense amplifiers 321a to 323a. In an example case in which the first control signal Ctrl1 is enabled, a first reference current Iref1, a second reference current Iref2, and a third reference current Iref3 may be input to the plurality of sense amplifiers 321a to 323a. In an example case in which the second control signal Ctrl2 is enabled, the second reference current Iref2, the third reference current Iref3, and the first reference current Iref1 may be input to the plurality of sense amplifiers 321a to 323a. Additionally, in an example case in which the third control signal Ctrl3 is enabled, the third reference current Iref3, the first reference current Iref1, and the second reference current Iref2 may be input to the plurality of sense amplifiers 321a to 323a.

Each of the plurality of demultiplexers 331a to 333a may include a plurality of switch circuits controlled by the plurality of control signals Ctrl1 to Ctrl3. In an example case in which each of the plurality of switch circuits is turned on, the comparison result signal may be provided as one of a plurality of inputs of the encoder. The switch circuits may be implemented with transistors.

Each of the plurality of demultiplexers 331a to 333a may interlock with the plurality of multiplexers 311a to 313a by the plurality of control signals Ctrl1 to Ctrl3. In an example case in which the first control signal Ctrl1 is enabled, the first multiplexer 311a may provide the first reference current Iref1 to the first sense amplifier 312a. Additionally, the first demultiplexer 331a, which interlocks with the first multiplexer 311a, provides the comparison result signal output from the first sense amplifier 312a to a first input terminal I1 corresponding to the first reference current Iref1. Similarly, the second multiplexer 312a may provide the second reference current Iref2 to the second sense amplifier 322, and the second demultiplexer 332a may provide the comparison result signal to a second input terminal I2 corresponding to the second reference current Iref2. Additionally, the third multiplexer 313a may provide the third reference current Iref3 to the third sense amplifier 323a, and the third demultiplexer 333a may provide the comparison result signal to a third input terminal I3 corresponding to the third reference current Iref3. Similarly, in an example case in which the second control signal Ctrl2 is enabled and the third control signal Ctrl3 is enabled, each of the plurality of demultiplexers 331a to 333a may interlock with the plurality of multiplexers 311a to 313a.

FIG. 9 is a view illustrating a priority encoder according to an example embodiment of the disclosure in detail.

Referring to FIG. 9, an encoder 340a according to an embodiment is illustrated. For example, the encoder 340a may correspond to any of the plurality of encoders 341a to 343a in FIG. 8. The encoder 340a may receive a first comparison result signal having a first reference current Iref1 through input terminal I1, a second comparison result signal having a second reference current Iref2 through input terminal I2, and a third comparison result signal having a third reference current Iref3 through input terminal I3. For example, the encoder 340a may receive the first reference current Iref1, the second reference current Iref2, and the third reference current Iref13 from a demultiplexer connected to the encoder 340a, in a given order. The encoder 340a may receive a power supply voltage VCC through an input terminal I0. According to an embodiment, the encoder 340a may further include a plurality of buffers for maintaining the received comparison result signals while the first to third comparison result signals are collected.

In an example embodiment, the encoder 340a may include a plurality of OR gates OR1, OR2 and OR3, an inverter INV, and an AND gate AND. The encoder 340a may have a value of ‘1’ among the comparison result signals received through the first to third input terminals I1 to I3, and may output an output signal O1 and an output signal O0 by encoding a signal having the highest priority. The encoder 340a may further output a valid signal V indicating whether the output signals O1 and O0 are valid.

The ADC circuit of the neuromorphic device described with reference to FIGS. 1 to 9 may improve the parallelism of a plurality of sense amplifiers by inputting different read currents and different reference currents to each of a plurality of sense amplifiers. Accordingly, the time required to convert read currents into digital signals may be reduced, and the MAC operation performance of a plurality of neuromorphic devices may be improved.

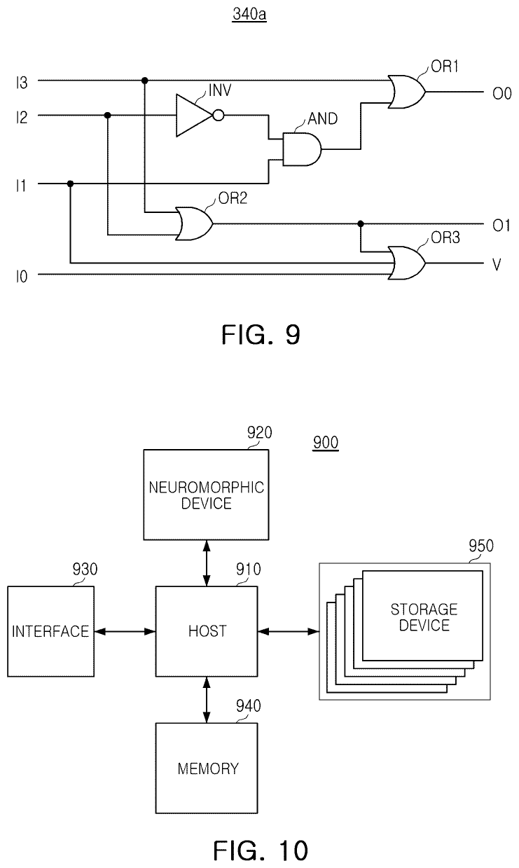

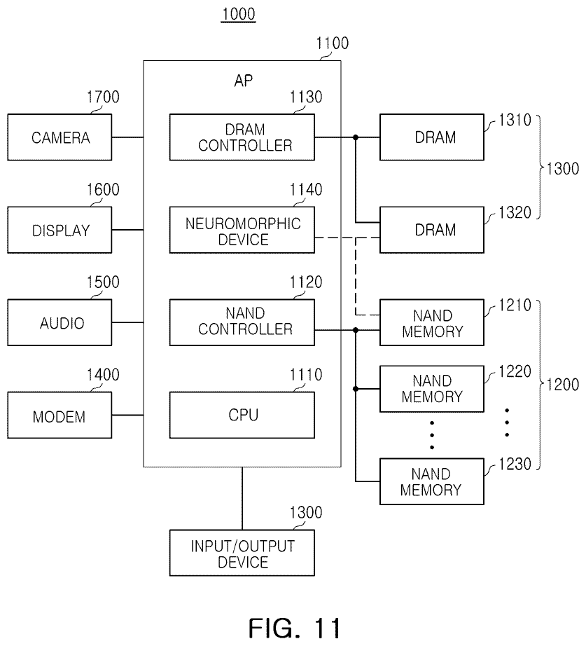

Hereinafter, examples of semiconductor devices to which a neuromorphic device according to an example embodiment of the disclosure may be applied are described with reference to FIGS. 10 and 11.

FIGS. 10 and 11 are schematic views illustrating a semiconductor device including a neuromorphic device according to an example embodiment of the disclosure.

Referring to FIG. 10, according to an example embodiment of the disclosure, a neuromorphic device 920 may be included in an electronic device 900. For example, the neuromorphic device 920 may be included in the electronic device 900 in a stand-alone form. For example, in addition to the neuromorphic device 920, the electronic device 900 may include a host 910, an interface 930, a memory 940, and a storage unit 950. However, the disclosure is not limited thereto, and as such, according to another embodiment, the electronic device 900 may include one or more other components or omit one or more components. According to an embodiment, the electronic device 900 may be an application server or storage server deployed in a data center, and the like, and may be connected to a network through the interface 930.

The host 910 may be a central processing unit (CPU) configured to control an overall operation of the electronic device 900, and may be implemented with a processor. The processor may be a single core processor or a multi-core processor. However, the disclosure is not limited thereto, and as such, according to another embodiment, the host 910 may include a CPU, a controller, or another type of circuitry to control an overall operation of the electronic device 900. According to an embodiment, the host 910 may record data in the storage unit 950 including a plurality of storage devices, or may read data stored in the storage unit 950 or delete the data stored in the storage unit 950. The memory 940 may be implemented as a dynamic random access memory, and the like, and the host 910 may execute instructions and/or data loaded into the memory 940.

The neuromorphic device 920 may perform neuromorphic calculations necessary for an operation of the electronic device 900, and may be implemented in the stand-alone form. In other words, in an example embodiment illustrated in FIG. 10, the neuromorphic device 920 may be implemented as a separate device from the host 910, and for example, the neuromorphic device 920 and the host 910 may be included in the electronic device 900 in the form of additional packages.

In an example embodiment of the disclosure, the host 910 may process some of the neuromorphic operations of the neuromorphic device 920, and handover results from processing some of the neuromorphic operations to the neuromorphic device 920. For example, the host 910 may be configured to perform a first set of neuromorphic operations and the neuromorphic device 920 may be configured to perform a second set of neuromorphic operations. The first set of neuromorphic operations may correspond to a first type of operations and the second set of neuromorphic operations may correspond to a second type of operations. The second set of neuromorphic operations performed by the neuromorphic device 920 may use results from the first set of neuromorphic operations performed by the host 910. For example, the neuromorphic device 920 may execute a MAC operation corresponding to a pre-trained neural network, as described above, and may process the MAC operation by quantizing each of weights and input values of one of layers of the neural network.

The neuromorphic device 920 may include a plurality of memory cells for storing weights corresponding to the plurality of layers included in the neural network. In an example embodiment, the plurality of memory cells may be included in one memory cell array or may be distributed in a plurality of memory cell arrays.

The neuromorphic device 920 may output weights stored in the plurality of memory cells in one memory cell array, and read currents corresponding to the operation results of input values transmitted to the plurality of memory cells through a plurality of word lines, through a plurality of bit lines. The ADC circuit may be connected to the one memory cell array, and the ADC circuit may be configured to convert the read currents into the digital signals by comparing the read currents with the reference currents.

According to an example embodiment of the disclosure, the ADC circuit may improve the parallelism of the operation of converting the read currents into the digital signals by simultaneously performing comparison operations of comparing the plurality of read currents with different reference currents. Accordingly, the performance of the neuromorphic device 920 may be improved.

Referring to FIG. 11, according to an example embodiment of the disclosure, a neuromorphic device 1140 may be included in an application processor AP 1100. For example, the neuromorphic device 1140 may be implemented in the form of a system-on-chip. For example, the neuromorphic device 1140 may be included in the application processor AP 1100 along with a CPU 1110, a NAND controller 1120, and a DRAM controller 1130. However, the disclosure is not limited thereto, and as such, the application processor AP 1100 may include one or more other components or omit one or more components. In an example embodiment illustrated in FIG. 11, the electronic device 1000 may be a mobile device such as a laptop computer, a mobile phone, a smart phone, a tablet personal computer (PC), a wearable device, a healthcare device, or Internet-of-Things (IoT).

Referring to FIG. 11, the electronic device 1100 may include an input/output device 1300, a modem 1400, an audio 1500, a display 1600, a camera 1700, an application processor 1100, one or more DRAMs 1300, and one or more NAND memories 1200. The one or more DRAMs 1300 may include a plurality of DRAMs 1310 to 1320 and the one or more NAND memories 1200 may include a plurality of NAND memories 1210 to 1230.

The modem 1400 may modulate and transmit signals for wired/wireless data transmission and reception, while demodulating original data from signals received from the outside. The input/output device 1300 is a device configured to provide digital input/output, and may include input devices such as a port capable of being connected to external recording media, a touch screen or a mechanical button key, and output devices capable of outputting vibration through a haptic method or the like.

The audio 1500 may process and output audio data stored inside the electronic device 1000, or audio data included in a network content received externally through the modem 1400 or the input/output device 1300.

The display 1600 may be implemented in various forms such as Liquid Crystal Display (LCD), Organic Light Emitting Diodes (OLED) display, Active-Matrix Organic Light-Emitting Diode (AM-OLED), Plasma Display Panel (PDP), Field Emission Display (FED), electronic paper, and the like. The display 1600 may be also used as an input device for the electronic device 1000 by providing a touch screen function, or may be provided integrally with a fingerprint sensor or the like, to provide a security function of the mobile system 1000.

The camera 1700 may capture still images or moving images under user control. The electronic device 1000 may obtain and recognize specific information using the still images and the moving images captured by the camera 1700 and provides related information, and may convert the still images and the moving images into other forms of data such as a text and store a content thereof. According to an embodiment, the electronic device 1000 may recognize a character string included in the still images/moving images captured by the camera 1700 and may provide a text/audio translation of text corresponding to the character string.

The application processor 1100 controls an overall operation of the electronic device 1000. Specifically, the application processor 1100 may control the display 1600 so that a portion of the content stored in the NAND memory 1200 is displayed on the display 1600. Additionally, the application processor 1100 may perform control operations corresponding to user input received through the input/output device 1300, etc.

The application processor 1100 may be provided as a system-on-chip (SoC) running an application program, an operating system (OS), and the like. Accordingly, the application processor 1100 may include a CPU 1110 that executes operations or runs an application program and/or an operating system, and various other peripheral components connected to the CPU 1110 through a system bus. The peripheral components may include a DRAM controller 1130, a neuromorphic device 1140, a NAND controller 1120, an internal memory, a power management block, an error detection block, and a monitoring block. The CPU 1110 may include one or more cores.

In an example embodiment, the neuromorphic device 1140 may include dedicated circuitry for neuromorphic operations. The neuromorphic device 1140 may be directly connected to at least one of DRAM 1300 and/or NAND memory 1200, and may include an arithmetic circuit for implementing the neural network as described above. The neuromorphic device 1140 may include an analog circuit or a digital circuit for AI data calculation.

Additionally, the neuromorphic device 1140 may include a plurality of unit ADC circuits performing conversion operations for each of the read currents so as to convert the read currents output through the bit lines from the memory cell array into the digital signals. Each of the plurality of unit ADC circuits may perform a plurality of comparison operations simultaneously by comparing different read currents with different reference currents. Accordingly, the performance of the neuromorphic device 1140 may be improved.

The disclosure is not limited to the above-described embodiments and the accompanying drawings but is defined by the appended claims. Therefore, those of ordinary skill in the art may make various replacements, modifications, or changes without departing from the scope of the disclosure defined by the appended claims, and these replacements, modifications, or changes should be construed as being included in the scope of the disclosure.

What is claimed is:

1. A neuromorphic device comprising:
a first memory cell array comprising a plurality of first memory cells configured to store weights of a neural network;
a second memory cell array comprising a plurality of second memory cells;
a word line driver connected to the plurality of first memory cells through a plurality of first word lines and connected to the plurality of second memory cells through a plurality of second word lines; and
an analog-to-digital converter (ADC) circuit connected to the plurality of first memory cells through a plurality of first bit lines and connected to the plurality of second memory cells through a plurality of second bit lines, the ADC circuit comprising:
a plurality of sense amplifiers, and
a plurality of encoders,
wherein each of the plurality of sense amplifiers is configured to compare a respective read current among a plurality of read currents output through the plurality of first bit lines with each of a plurality of reference currents output through the plurality of second bit lines, and respectively output comparison result signals, and
wherein each of the plurality of encoders is connected to a respective sense amplifier among the plurality of sense amplifiers, and each of the plurality of encoders configured to:
collect the comparison result signals output from the respectively connected sense amplifiers until the read current from the respectively connected sense amplifier is compared with all of the plurality of reference currents, and
output digital signals based on the collected comparison result signals.

2. The neuromorphic device of claim 1, wherein the ADC circuit further comprises:
a plurality of multiplexers, each of the plurality of multiplexers connected between a respective sense amplifier among the plurality of sense amplifiers and the plurality of second bit lines, and configured to respectively output one reference current among the plurality of reference currents to the respective sense amplifier, and
a plurality of demultiplexers, each of the plurality of demultiplexers connected between a respective sense amplifier among the plurality of sense amplifiers and a respective encoder among the plurality of encoders, and each of the plurality of demultiplexers configured to provide a comparison result signal output from the respective sense amplifier as one of a plurality of input signals of the respective encoder based on the reference current input to the respective sense amplifier.

3. The neuromorphic device of claim 2, wherein the ADC circuit further comprises a control circuit configured to control the plurality of multiplexers,
wherein each of the plurality of multiplexers comprises a plurality of first switch circuits, each of the plurality of first switch circuits connected between a respective second bit line among the plurality of second bit lines and the respective sense amplifier, and
wherein the control circuit is further configured to turn on one switch circuit among the plurality of first switch circuits in each of the plurality of multiplexers so that each of the plurality of sense amplifiers is connected to different second bit lines among the plurality of second bit lines.

4. The neuromorphic device of claim 3, wherein each of the plurality of demultiplexers comprises a plurality of second switch circuits, each of the plurality of second switch circuits is connected between the respective sense amplifier and a respective input terminal among a plurality of input terminals included in the respective encoder, and
wherein the control circuit is further configured to turn on one switch circuit corresponding to a reference current input to the one sense amplifier among the plurality of second switch circuits, in each of the plurality of demultiplexers.

5. The neuromorphic device of claim 2, wherein each of the plurality of encoders comprises a plurality of input terminals configured to receive a plurality of input signals having different priorities, and generate a first digital signal by encoding an input signal having a highest priority among the plurality of input signals.

6. The neuromorphic device of claim 5, wherein each of the plurality of demultiplexers is configured to provide a comparison result signal generated based on a reference current of a higher magnitude among the comparison result signals to the respective encoder as an input signal having a higher priority.

7. The neuromorphic device of claim 1, wherein a number of the plurality of second bit lines is 2^{L}−1 based on a number of bits of the digital signals is L, and wherein L is a natural number.

8. The neuromorphic device of claim 1, wherein a number of the plurality of sense amplifiers and a number of the plurality of encoders are respectively equal to a number of the plurality of second bit lines.

9. The neuromorphic device of claim 8, wherein a number of the plurality of first bit lines and the number of the plurality of second bit lines are equal to each other.

10. The neuromorphic device of claim 8, wherein a number of the plurality of first bit lines is larger than the number of the plurality of second bit lines, and
wherein the ADC circuit is further configured to:
select a same number of read currents as the number of the plurality of second bit lines among the plurality of read currents output through the plurality of first bit lines, and
repeat an operation of outputting the digital signals of the selected read currents using the plurality of sense amplifiers and the plurality of encoders until the digital signals for all of the plurality of read currents are output.

11. The neuromorphic device of claim 1, wherein the plurality of first memory cells and the plurality of second memory cells comprise a same type of resistive material.

12. A neuromorphic device comprising:
a memory cell array comprising a plurality of memory cells configured to store weights of a neural network;
a word line driver connected to the plurality of memory cells through a plurality of word lines; and
an analog-to-digital converter (ADC) circuit connected to the plurality of memory cells through a plurality of bit lines, the ADC circuit configured to:
repeat a comparison operation and a collection operation, the comparison operation comprising simultaneously comparing each of a plurality of read currents output through the plurality of bit lines with different reference currents among a plurality of reference currents, and the collection operation comprising collecting comparison result signals of each of the read currents until each of the read currents is compared with all of the plurality of reference currents, and
convert the read currents into digital signals based on the comparison result signals collected for each of the read currents.

13. The neuromorphic device of claim 12, wherein the ADC circuit is configured to:
pair the plurality of read currents and the plurality of reference currents based on an order of the plurality of read currents determined based on identifiers of the plurality of bit lines, and an order of the plurality of reference currents based on depending on magnitudes of the plurality of reference currents, and
simultaneously compare a plurality of read current and reference current pairs, respectively.

14. The neuromorphic device of claim 13, wherein the ADC circuit is configured to:
based on each of the read currents not being compared to all of the plurality of reference currents, change the paired reference current to a reference current in a next order based on the order of the plurality of reference currents, in the plurality of read current and reference current pairs.

15. The neuromorphic device of claim 12, wherein the ADC circuit is configured to:
convert the read currents into the digital signals by performing priority encoding on the comparison result signals collected for each of the read currents.

16. The neuromorphic device of claim 12, wherein the neuromorphic device further comprises an addition circuit for generating output data by performing accumulation or summation operations using the digital signals.

17. A neuromorphic device comprising:
a memory cell array comprising a plurality of memory cells configured to store weights of a neural network;
a word line driver connected to the plurality of memory cells through a plurality of word lines; and
an analog-to-digital converter (ADC) circuit connected to the plurality of memory cells through a plurality of bit lines, the ADC comprising:
a plurality of unit circuits, each of the plurality of unit circuits configured to:
generate comparison result signals by comparing one read current among a plurality of read currents output through the plurality of bit lines with a plurality of reference currents sequentially,
collect the comparison result signals until the one read current is compared with all of the plurality of reference currents, and
output a first digital signal based on the collected comparison result signals,
a control circuit configured to control the plurality of unit circuits to simultaneously perform a comparison operation using different reference currents.

18. The neuromorphic device of claim 17, wherein a number of the plurality of unit circuits is equal to a number of the plurality of reference currents.

19. The neuromorphic device of claim 17, wherein the control circuit is configured to,
based on a number of the plurality of read currents being larger than a number of the plurality of unit circuits, select target read currents simultaneously input to each of the plurality of unit circuits among the plurality of read currents.

20. The neuromorphic device of claim 17, wherein each of the plurality of unit circuits comprises:
a multiplexer configured to select one reference current among a plurality of reference currents based on a control signal output by the control circuit;
a sense amplifier configured to output one comparison result signal among the comparison result signals by comparing one read current among the plurality of read currents output through the plurality of bit lines with the selected reference current;
a priority encoder configured to output a second digital signal based on a plurality of input signals, and
a demultiplexer configured to input the comparison result signals as one input signal among the plurality of input signals to the priority encoder.
